(19) United States
(12) Patent Application Publication
(10) Pub. No.: US 2009/0201230 A1
(43) Pub. Date: Aug. 13, 2009

(54) Active Matrix Organic Electro-Optic Devices

(75) Inventor: Euan C. Smith, Cambridgeshire (GB)

Correspondence Address: MARSHALL, GERSTEIN & BORUN LLP, 233 SOUTH WACKER DRIVE, 6300 SEARS TOWER, CHICAGO, IL, 60606-6357, US

(73) Assignee: CAMBRIDGE DISPLAY TECHNOLOGY LIMITED, Cambridgeshire (GB)

(21) Appl. No.: 12/307,039

(22) PCT Filed: Jun. 28, 2007
(86) PCT No.: PCT/GB2007/002435

§ 371 Date: Jan. 19, 2009

(30) Foreign Application Priority Data
Jun. 30, 2006 (GB) 0612973.8

(51) Int. Cl. G09G 3/30

(52) U.S. Cl. 345/76

(57) ABSTRACT

This invention generally relates to active matrix organic electro-optic devices and to related display driving methods. In embodiments the invention relates to top-emitting OLED (Organic Light Emitting Diode) displays including additional circuitry which may be employed for display driving or other functions.

An active matrix organic electro-optic device, the device having a plurality of pixels and comprising a substrate bearing pixel interface circuitry for each of said pixels and organic material over said pixel interface circuitry, wherein said device is configured such that over at least a part of an area of said device said pixel interface circuitry is staggered with respect to said pixels such that a region under at least one of said pixels is incompletely occupied by said pixel interface circuitry, and wherein additional circuitry for said device is fabricated in said region incompletely occupied by said pixel interface circuitry.

This invention generally relates to active matrix organic electro-optic devices. In embodiments the invention relates to top-emitting OLED (Organic Light Emitting Diode) displays including additional circuitry which may be employed for display driving or other functions, and to related display driving methods.

### Organic Light Emitting Diode Displays

Displays fabricated using OLEDs provide a number of advantages over LCD and other flat panel technologies. They are bright, colourful, fast-switching (compared to LCDs), provide a wide viewing angle and are easy and cheap to fabricate on a variety of substrates. Organic (which here includes organometallic) LEDs may be fabricated using materials including polymers, small molecules and dendrimers, in a range of colours which depend upon the materials employed. Examples of polymer-based organic LEDs are described in WO 90/13148, WO 95/06400 and WO 99/48160; examples of dendrimer-based materials are described in WO 99/21935 and WO 02/067343; and examples of so called small molecule based devices are described in U.S. Pat. No. 4,539,507.

A typical OLED device comprises two layers of organic material, one of which is a layer of light emitting material such as a light emitting polymer (LEP), oligomer or a light emitting low molecular weight material, and the other of which is a layer of a hole transporting material such as a polythiophene derivative or a polyaniline derivative.

Organic LEDs may be deposited on a substrate in a matrix of pixels to form a single or multi-colour pixelated display. A multicoloured display may be constructed using groups of red, green, and blue emitting pixels. So-called active matrix (AM) displays have a memory element, typically a storage capacitor and a transistor, associated with each pixel whilst passive matrix displays have no such memory element and instead are repetitively scanned to give the impression of a steady image. Examples of polymer and small-molecule active matrix display drivers can be found in WO 99/42983 and EP 0,717,446A respectively.

A display may be either bottom-emitting or top-emitting. In a bottom-emitting display light is emitted through the substrate on which the active matrix circuitry is fabricated; in a top-emitting display light is emitted towards a front face of the display without having to pass through a layer of the display in which the active matrix circuitry is fabricated.

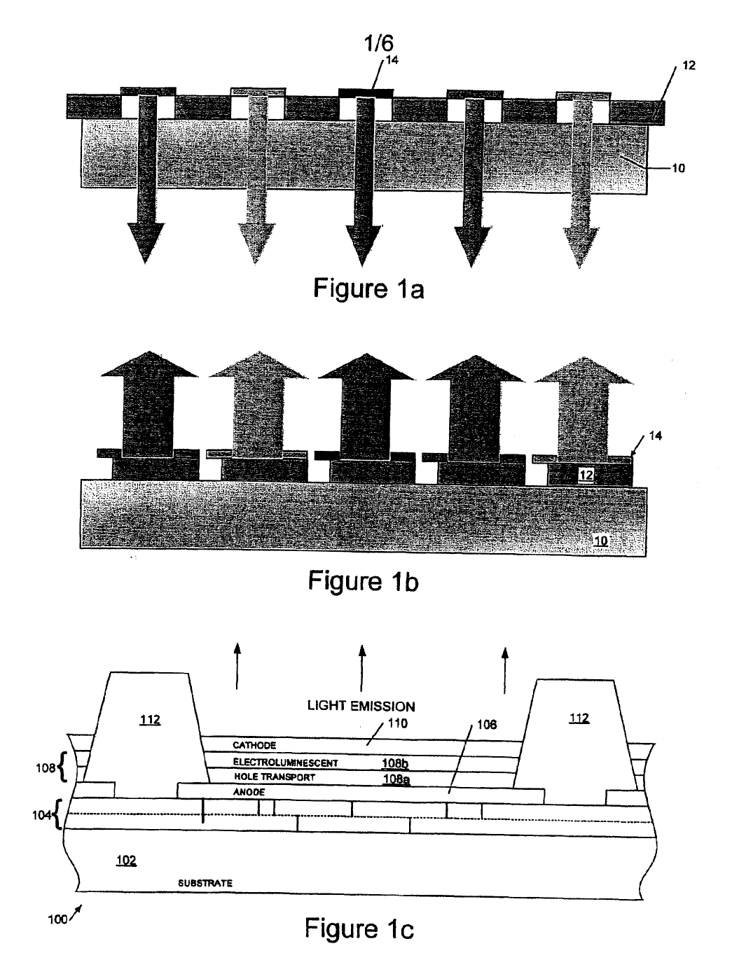

FIGS. 1a and 1b show schematic diagrams of a bottom-emitting and of a top-emitting OLED display respectively. In FIGS. 1a and 1b a substrate 10 bears an active matrix driver circuit 12 for each pixel, over which is provided an OLED pixel 14. It can be seen from FIG. 1a that, broadly speaking, in a bottom-emitting OLED display (or in an LCD display) a display pixel lies in a region which is unoccupied by the active matrix electronics. In a top-emitting display, however, this is not the case.

Top-emitting OLED displays are less common than bottom-emitting displays because, typically, the upper electrode comprises the cathode and this must be at least partially transparent, as well as having sufficient conductivity and, preferably, providing a degree of encapsulation of the underlying organic layers. Nonetheless a large variety of top-emitting structures has been described, including in the applicant's published PCT application WO 2005/071771 (hereby incorporated by reference in its entirety) which describes a cathode incorporating an optical interference structure to enhance the amount of light escaping from the OLED pixel.

### Example Top Emitting OLED Structure

FIG. 1c shows a vertical cross section through part of a top-emitting active matrix OLED display 100 (somewhat simplified for the purposes of illustration).

In this example the display has a glass or plastic substrate 102 supporting a plurality of polysilicon and/or metallisation and insulating layers 104 in which the drive circuitry (as shown, including vias) is formed. The uppermost layer of this set of layers comprises an insulating and passivating oxide layer (SiO₂) over which an anode layer 106 is deposited. This anode may comprise a conventional metal layer such as a platinum layer. As the display is top-emitting a non-transparent substrate, for example steel, may also be employed.

One or more layers of OLED material 108 are deposited over anode 106, for example by spin coating and subsequent patterning, or by selective deposition using an inkjet-based deposition process (see, for example, EPO 880 303 or WO2005/076386). In the case of a polymer-based OLED layers 108 comprise a hole transport layer 108a and a light emitting polymer (LEP) electroluminescent layer 108b. The electroluminescent layer may comprise, for example, PPV (poly(p-phenylenevinylene)) and the hole transport layer, which helps match the hole energy levels of the anode layer and of the electroluminescent layer, may comprise, for example, PEDOT: PSS (polystyrene-sulphonate-doped polyethylene-dioxythiophene).

A multilayer cathode 110 overlies the OLED material 108 and, in a top-emitting device, is at least partially transparent at wavelengths at which the device is designed to emit. For a polymer LED the cathode preferably has a work function of less than 3.5 eV and may comprise a first layer having a low work function, for example a metal such as calcium, magnesium or barium, and a second layer adjacent the LEP layer 108b providing efficient electron injection, for example of barium fluoride or another metal fluoride or oxide. The top layer of cathode 110 (that is the layer furthest from LEP 108b) may comprise a thin film of a highly conductive metal such as gold or silver. Metallic layers having a thickness of less than 50 nm, more preferably less than 20 nm have been found to be sufficiently optically transparent although it is preferable that the sheet resistance is kept low, preferably less than 100 ohms/square, more preferably less than 30 ohms/square. The cathode layer may be used to form cathode lines which can be taken out to contacts at the side of the device. In some configurations the anode, OLED material, and cathode layers may be separated by banks (or wells) such as banks 112 formed, for example, from positive or negative photoresist material at an angle of approximately 15° to the plane of the substrate (in FIG. 1 they are shown steeper for ease of representation).

The inventors have recognised that a top-emitting OLED structure facilitates the incorporation of additional functionality.

### SUMMARY OF THE INVENTION

According to a first aspect of the invention there is therefore provided an active matrix organic electro-optic device, the device having a plurality of pixels and comprising a substrate bearing pixel interface circuitry for each of said pixels and organic material over said pixel interface circuitry, wherein said device is configured such that over at least a part of an area of said device said pixel interface circuitry is staggered with respect to said pixels such that a region under at least one of said pixels is incompletely occupied by said pixel interface circuitry, and wherein additional circuitry for said device is fabricated in said region incompletely occupied by said pixel interface circuitry.

The inventors have recognised that in a structure of the general type used in a top-emitting display the active matrix drive circuitry can be spatially offset to make space for additional circuitry. This additional, non-pixel aligned circuitry can be used to add functionality and/or improve the performance of an OLED display, taking advantage of the lessened requirement, with top-emitting displays, of exact co-location of a pixel and its drive circuitry. Thus the additional functionality may comprise, for example, signal boosting or regeneration to reduce programming times, performance sampling circuitry such as calibration circuitry or age detection compensation circuitry, light detection circuitry, or circuitry for implementing a touch sensor, to provide a touch-sensitive display. Thus in some preferred embodiments the additional circuitry comprises active circuitry including at least one semiconductor device.

In some preferred embodiments the organic electro-optic device comprises a top-emitting active matrix OLED display, the organic material over the pixel interface circuitry comprising OLED material. In such embodiments the interface circuitry preferably comprises pixel drive circuitry. However applications of the concept are not limited to top-emitting active matrix OLED structures and may be employed with other types of top-emitting electro-luminescent structure as well as in the context of other similar structures, for example including (but not limited to) photovoltaic (PV) device structures, and sensor structures.

Preferably the interface drive circuitry is staggered with respect to the pixels such that a region under a pair of adjacent pixels is incompletely occupied by this circuitry. In embodiments the regions incompletely occupied by the interface or drive circuitry are provided at regular intervals across an area of the display, for example each in association with a group of pixels. The additional circuitry may then comprise shared interface drive circuitry, for example to provide a drive signal to such a group of pixels. For example such shared drive circuitry may be provided at intervals along a data line for a row and/or column of the display. It will be appreciated that in embodiments this can be implemented without causing any undesirable artefacts in the appearance of the display.

The shared drive circuitry may comprise a signal regeneration circuit. In particular active matrix drive circuits or OLED display pixels are often current controlled (because this facilitates obtaining a substantially linear response from the display) and the active matrix drive circuitry for a pixel may therefore comprise current drive circuitry. More particularly this current drive circuitry may be programmed by a current on a row or column data line and, unless the active matrix pixel itself incorporates a current mirror or other current scaling circuit or arrangement the programming current may correspond, at least in order of magnitude to the OLED current. However the OLED current can be small, for example of order 1 μA. In other arrangements (described later) the OLED pixel current is defined, in part, by the current through a photo diode associated with the pixel (to compensate for aging), and in this case because the photon efficiency of the photo diode may only be of order 1% the programming current may only be of order 10 nA. However a problem with the very small currents is that data line capacitance and/or leakage currents can have a significant impact on the programming current with which a pixel is driven. In some preferred embodiments, therefore, the shared drive circuitry comprises circuitry to provide a drive signal gain of less than unity, in particular to attenuate or down scale a current drive signal. For example the shared drive circuitry may comprise a de-amplifying current mirror. In this way a relatively larger current drive signal may be provided on a pixel data line, the drive signal being scaled down at a location which is (preferably) physically close to the driven pixel.

In some preferred embodiments the additional circuitry includes a select or enable circuit, in particular to select or enable the additional circuitry (for example shared drive circuitry) when driving a pixel of a group of pixels with which the additional circuitry is associated. In some preferred embodiments the additional circuitry also includes a memory element, for example in the case of shared drive circuitry to store a drive signal for driving a pixel of a group of pixels with which the additional (shared drive) circuitry is associated. This facilitates a method of driving the display as described below.

Additionally or alternatively the additional circuitry may include a light or touch sensor, for example to provide a touch-sensitive display.

In a related aspect the invention provides a method of driving a pixelated display, the display having a plurality of active matrix pixels each with a data line for writing display data to the pixel, a said data line being shared for driving a plurality of pixels of said display, pixels driven by a said shared data line being allocated to groups, each group comprising multiple pixels and having a respective group data driver circuit coupled to said shared data line and to each pixel of the group for receiving pixel drive data from said shared data line and for driving a selected pixel of the group responsive to said pixel drive data, the method comprising: driving a first pixel of each of said groups in turn; and then driving a second pixel of each of said groups in turn.

Preferably the method comprises driving each pixel of each group, driving each group in turn and, for each group, each pixel of each group in turn. In this way all the pixels in all the groups associated with the shared data line may be addressed.

In some preferred embodiments the shared data line comprises a row or column data line of the display. In colour display embodiments the pixels may comprise colour sub-pixels, in particular of the same colour, for example red, green or blue.

Preferably the driving includes storing a drive signal for a pixel of each group so that a pixel in one group may be driven while another group is selected and pixel data written (and stored). Thus the method may comprise writing to a first group, more particularly to a pixel within this group, and then this first group (or the pixel within the group) waits until the other group or groups are written. In this way in embodiments of the method with, say, n groups each pixel has a programming time which is extended by a factor of n.

As mentioned above, in some preferred embodiments the driving of a pixel comprises buffering a drive signal on the shared data line using the group driver circuit, and driving the pixel with the buffered drive signal. This is particularly advantageous as display sizes increase since the longer write-cycle programming times reduce the effects of data line capacitance. In embodiments the buffering comprises reducing a level of a current drive signal to an active matrix pixel drive circuit, for example using a current mirror circuit to de-amplify a level of the current drive signal. In this way the data line current may be significantly larger, for example, by greater than a factor of 10, 50 or 100, than a current drive to an active matrix pixel drive circuit. In conjunction with using, say, 10, 50 or 100 groups of pixels an improvement by a factor of 10² to 10⁴ may be achieved.

Preferably the group data driver circuit is located adjacent a pixel in a group driven by the circuit. Preferably, as described above, active matrix drive circuitry for pixels of a group is displaced to allow the group data driver circuit to be included in the display alongside the active matrix circuitry for pixels of the group.

In some preferred embodiments of the method the display comprises a flat panel display (generally not fabricated on crystallised silicon, generally greater than 2 cm or 5 cm diagonal; by contrast with a chip-type display). Preferably the display comprises a top-emitting active matrix OLED display.

In a further related aspect the invention provides a pixelated display, the display having a plurality of active matrix pixels each with a data line for writing display data to the pixel, a said data line being shared for driving a plurality of pixels of said display, pixels driven by a said shared data line being allocated to groups, each group comprising multiple pixels and having a respective group data driver circuit coupled to said shared data line and to each pixel of the group for receiving pixel drive data from said shared data line and for driving a selected pixel of the group responsive to said pixel drive data.

These and other aspects of the invention will now be further described, by way of example only, with reference to the accompany figures in which:

FIGS. 1a to 1c show, respectively, a schematic diagram of a bottom-emitting OLED display, a schematic diagram of a top-emitting OLED display, and a vertical cross-section through a part of a top-emitting active matrix OLED display;

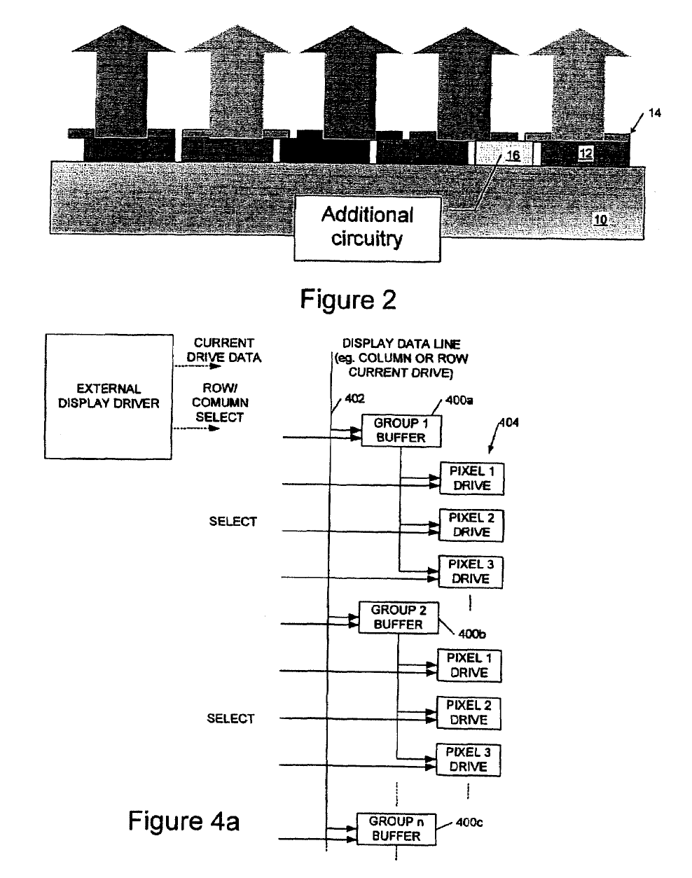

FIG. 2 shows an embodiment of a top-emitting active matrix OLED display according to the invention;

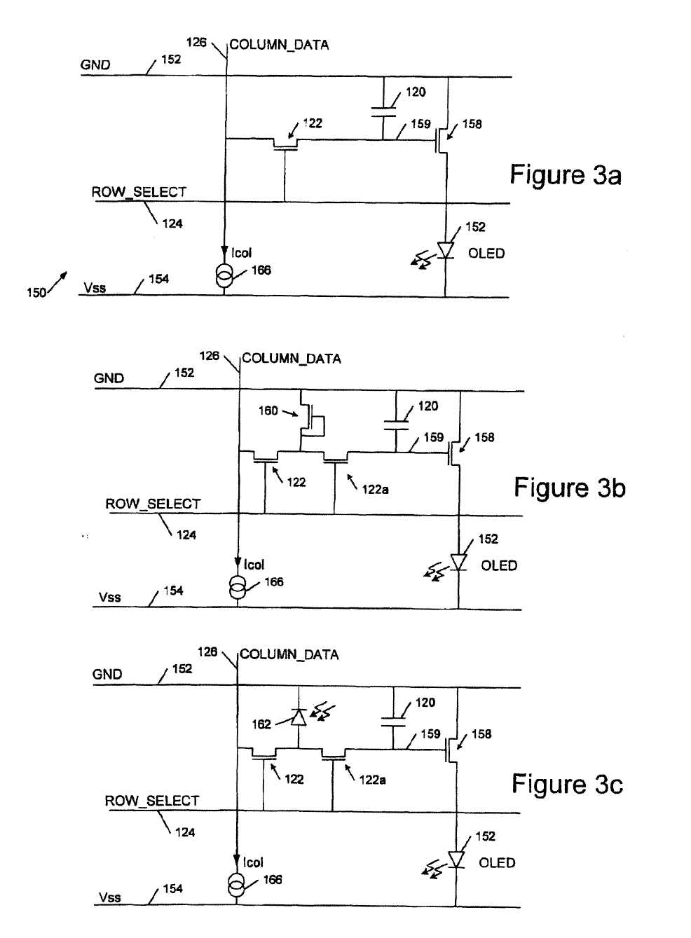

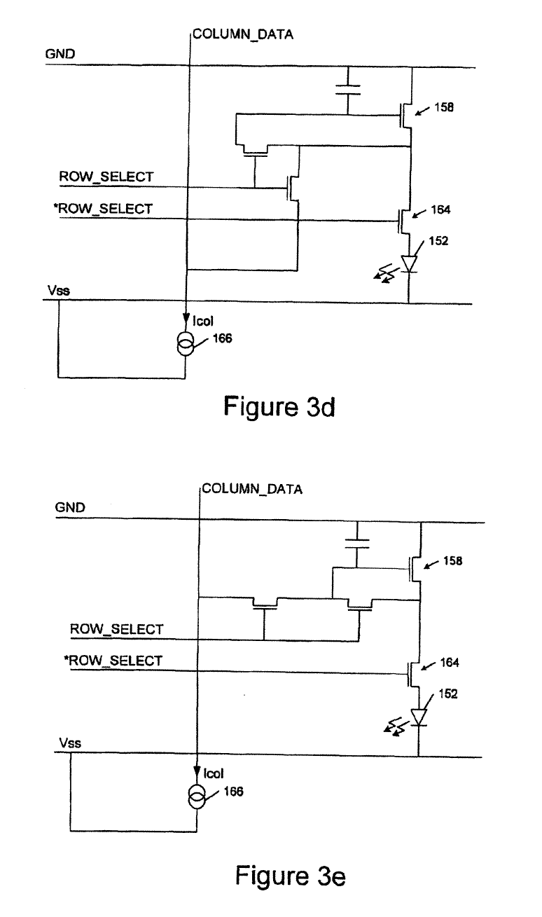

FIGS. 3a to 3e show examples of active matrix pixel driver circuits;

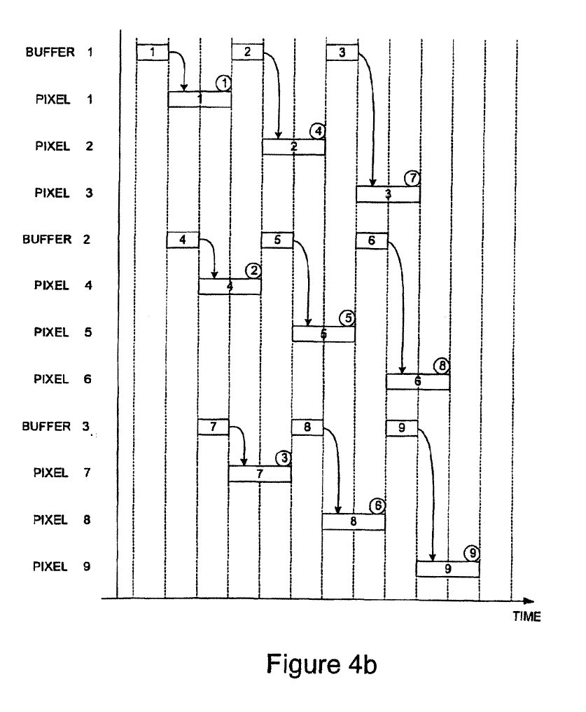

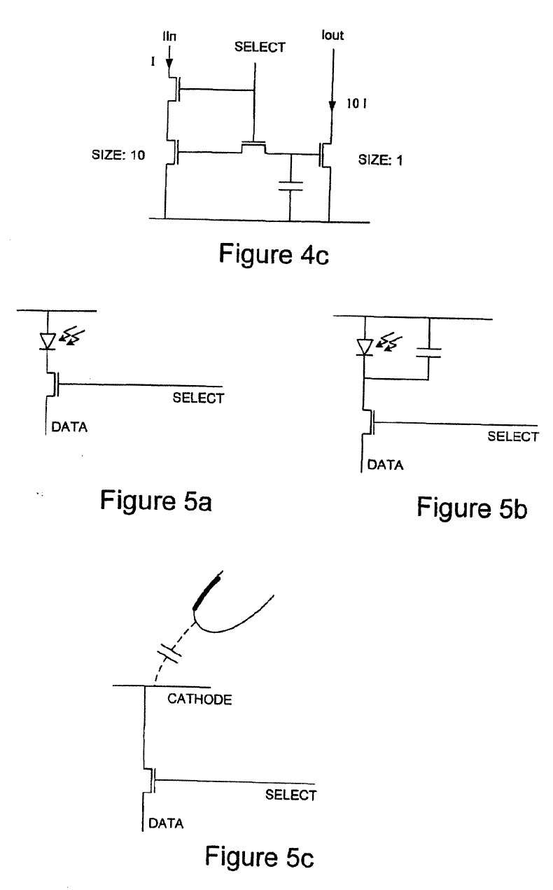

FIGS. 4a to 4c show, respectively, a drive signal buffer circuitry architecture for the top-emitting OLED display of FIG. 2, a driver signal timing diagram for the architecture of FIG. 4a, and a selectable, de-amplifying current mirror circuit incorporating a memory element, for use with the architecture of FIG. 4a; and

FIGS. 5a to 5c show, respectively, a first example of a light sensor circuit, a second example of a light sensor circuit, and an example of a touch-sensor circuit, all for use with embodiments of an active matrix top-emitting OLED display as shown in FIG. 2.

Referring to FIG. 2, this shows an embodiment of a top-emitting active matrix OLED display according to the invention, in which like elements to those of FIG. 1b are indicated by like reference numerals. It can be seen that in the configuration of FIG. 2 the active matrix pixel drive circuitry is staggered with respect to the pixels to leave a region 16 which is incompletely occupied by the pixel drive circuitry and which is instead occupied by additional circuitry between the pixel driver circuits.

In FIG. 2 the active matrix pixel drive circuitry and additional circuitry is illustrated schematically, as blocks, although in practice the circuits will be fabricated in a part of a continuous layer similar to layer 104 of FIG. 1c. A typical pixel pitch is of the order of 300 μm in a monochrome display, and of the order of 50 μm to 100 μm in an RGB colour display (as illustrated). As shown the pixel drive circuit area is less than the pixel area, which provides some redundant space and by shifting the pixel drive circuitry with respect to the pixel it drives over a distance of say 5 pixels to 20 pixels, for example around 10 pixels, sufficient redundant space may be created for the additional circuitry as shown. The space between pixels may be used for a photo diode sensor. Where the drive circuitry comprises organic thin film transistors (TFTs) or transistors fabricated in LTPS (Low Temperature Poly Silicon) these are generally p-type devices; where active matrix circuitry is fabricated in amorphous silicon the TFTs are generally n-type.

The additional circuitry of FIG. 2 can have many different functions, some examples of which are described in more detail below.

A first example relates to current programmed pixel circuits. Here, current leakage can cause a problem as the signals are very small and typically there are very many (for example 1024) connections to a data line. Thus as an alternative the data line may be routed to a smaller number (for example 32) of signal regeneration circuits which regenerate the data signal to a subset of the pixel circuits (for example 16 circuits or, again, 32 circuits). This facilitates the addressing of a large number of pixel circuits (32×32=1024) with much reduced issues of current leakage. The relationship can also be asymmetrical where a larger current is distributed to more regeneration circuits (for example 128 circuits). Then a de-amplifying current mirror may be employed to distribute the signal to a smaller number (for example 8) of pixel circuits.

We now describe a second, related example: some proposed pixel drive circuits have very complex designs but typically the majority of the components are only used during programming. Thus a programming portion of the pixel drive circuits may be shared between a number of pixels. However it will be appreciated that it will frequently be impractical to locate this shared circuitry at the edge of a display panel, for example because of matching requirements. Thus advantageously this circuitry may be implemented as additional circuitry between the pixel circuits, in particular shared between a small number of pixel circuits located locally. Such shared circuitry may be distributed at intervals throughout the display.

In a third example the additional circuitry comprises a light sensing circuit. This can be used to detect light from the emitting pixels reflected back towards the display panel by, for example, a finger or stylus, thus adding touch sensor functionality. Additionally or alternatively such light sensor circuitry could also function as a detector for background illumination so that, for example, the display can be controlled to operate at a luminance appropriate to the environment. Additionally or alternatively such light sensing circuitry may be employed to calibrate the light output from an OLED pixel, more particularly from one or more differently coloured pixels of a colour OLED display, for example to compensate for aging.

### Data Drive Architectures for Active Matrix Displays

FIG. 3a shows an example of a voltage controlled OLED active matrix pixel circuit 150. A circuit 150 is provided for each pixel of the display and ground 152, Vₛₛ 154, row select 124 and column data 126 busbars are provided interconnecting the pixels. Thus each pixel has a power and ground connection and each row of pixels has a common row select line 124 and each column of pixels has a common data line 126.

Each pixel has an OLED 152 connected in series with a driver transistor 158 between ground and power lines 152 and 154. A gate connection 159 of driver transistor 158 is coupled to a storage capacitor 120 and a control transistor 122 couples gate 159 to column data line 126 under control of row select line 124. Transistor 122 is a thin film field effect transistor (FET) switch which connects column data line 126 to gate 159 and capacitor 120 when row select line 124 is activated. Thus when switch 122 is on a voltage on column data line 126 can be stored on a capacitor 120. This voltage is retained on the capacitor for at least the frame refresh period because of the relatively high impedances of the gate connection to driver transistor 158 and of switch transistor 122 in its “off” state.

Driver transistor 158 is typically an FET transistor and passes a (drain-source) current which is dependent upon the transistor's gate voltage less a threshold voltage. Thus the voltage at gate node 159 controls the current through OLED 152 and hence the brightness of the OLED.

The voltage-controlled circuit of FIG. 3a suffers from a number of drawbacks, in particular because the OLED emission depends non-linearly on the applied voltage, and current control is preferable since the light output from an OLED is proportional to the current it passes. FIG. 3b (in which like elements to those of FIG. 3a are indicated by like reference numerals) illustrates a variant of the circuit of FIG. 3a which employs current control. More particularly a current on the (column) data line, set by current generator 166, “programs” the current through thin film transistor (TFT) 160, which in turn sets the current through OLED 152, since when transistor 122a is on (matched) transistors 160 and 158 form a current mirror. FIG. 3c illustrates a further variant, in which TFT 160 is replaced by a photodiode 162, so that the current in the data line (when the pixel driver circuit is selected) programs a light output from the OLED by setting a current through the photodiode.

FIG. 3d, which is taken from our application WO03/038790, shows a further example of a current-controlled pixel driver circuit. In this circuit the current through an OLED 152 is set by setting a drain source current for OLED driver transistor 158 using a current generator 166, for example a reference current sink, and memorising the driver transistor gate voltage required for this drain-source current. Thus the brightness of OLED 152 is determined by the current, I_{col}, flowing into reference current sink 166, which is preferably adjustable and set as desired for the pixel being addressed. In addition, a further switching transistor 164 is connected between drive transistor 158 and OLED 152. In general one current sink 166 is provided for each column data line. FIG. 3e shows a variant of the circuit of FIG. 3d.

A problem shared by current drive active matrix pixel circuits is that where, as is often the case, the pixel “programming” currents are small leakage and/or data line capacitance may dominate, particularly in large displays. One solution is to incorporate a de-amplifying current mirror in each pixel driver circuit, but this occupies space and may not provide sufficient benefit to outweigh the capacitance.

FIG. 4a shows a diagram of an OLED display architecture in which a pixel group buffer 400 is included at regular intervals along a display data line 402, for example every ten pixels. This group buffer may be physically incorporated into the display as the additional circuitry 16 shown in FIG. 2. Each group buffer 400 preferably provides a current de-amplification, for example by a factor of 10 to effectively provide a factor of 10 decrease in the influence of the data line capacitance. Each group buffer 400 drives a set of pixel drive circuits 404 and preferably, therefore, each group buffer includes a select line so that it may be selected, either separately to or at the same time as a pixel of the group with which it is associated.

In some preferred embodiments each group buffer circuit 400 also includes a memory element such as a capacitor so that the circuit can be selected and will store a value, in particular a current value for programming a pixel drive circuit, on display data line 402. This allows an increase in the programming time of each pixel drive circuit 404, thus still further reducing the effects of data line capacitance. For example where pixels along a data line are divided into 10 groups, a factor of 10 increase in the pixel “programming” time can be achieved, in this example providing an overall gain over sources of noise and capacitance of around one hundredfold.

FIG. 4b illustrates a timing of the programming of pixels along a data line, showing how the programming time for the pixels is increased. In the example of FIG. 4b there are 3 groups of pixels, each with 3 pixels. The pixels along the data line are labelled linearly corresponding to the labels on the y-axis of FIG. 4b. The order in which the pixels are written are indicated in circles; line numbers of the display are shown in the horizontal bars in FIG. 4b. Thus it can be seen that, because the group buffers 400 incorporate a memory element, a first group buffer may be written and the data in this retained (whilst group buffers 2 and 3 are written) until it comes time to write data into a group 1 pixel once more. In this way, because in the example there are 3 groups of pixels, the programming time for each pixel is extended by a factor of 3. As shown, a buffer is written in a first time interval and an associated pixel is programmed in a subsequent time interval. Alternatively a pixel and its associated buffer may be written simultaneously. In a preferred embodiment the buffer and pixel select lines shown in FIG. 4a are driven in accordance with the timing diagram shown in FIG. 4b, for example by a controller (not shown) so that, for example, the Pixel 1 select line is active during the period shown by the Pixel 1 bar in FIG. 4b.

FIG. 4c illustrates an example of a de-amplifying current mirror circuit, with a select line and a memory element, which may be employed to implement a group buffer 400. The de-amplification is achieved in the circuit of FIG. 4c by controlling the relative sizes of the two transistors of the current mirror, as indicated.

Referring to FIGS. 5a to 5c, these show further examples of additional circuitry which may be included in a display of the type shown in FIG. 2. FIG. 5a shows a photo diode selected by a select line and providing a light-sensing signal on an associated data line. FIG. 5b shows a variant of this circuit in which a capacitor is included in parallel with the photo diode. In operation, in the circuit of FIG. 5b a voltage may be written onto the capacitor and photodiode and this may then be read at a later point in time to determine the change in voltage, which depends upon the degree of discharge of the capacitor by the photodiode, and hence on the (integral of the) light received by the photo diode.

FIG. 5c illustrates a simple example of a touch sensor circuit in which a TFT has one of its source/drain connections to a cathode line of the display (compare FIG. 1c) where it can be seen that the cathode is towards the front face of the display. When the TFT of FIG. 5c is selected the circuit may be used to detect a capacitance, for example between the cathode line and a user's finger as illustrated.

Embodiments of the invention have been described with reference to top-emitting active matrix OLED structures but the techniques may also be applied, for example, to similar PV structures. No doubt many other effective alternatives will occur to the skilled person. It will be understood that the invention is not limited to the described embodiments and encompasses modifications apparent to those skilled in the art lying within the spirit and scope of the claims appended hereto.

1. An active matrix organic electro-optic device, the device having a plurality of pixels and comprising a substrate bearing pixel interface circuitry for each of said pixels and organic material over said pixel interface circuitry, wherein said device is configured such that over at least a part of an area of said device said pixel interface circuitry is staggered with respect to said pixels such that a region under at least one of said pixels is incompletely occupied by said pixel interface circuitry, and wherein additional circuitry for said device is fabricated in said region incompletely occupied by said pixel interface circuitry.

2. An organic electro-optic device as claimed in claim 1 wherein said device is configured such that over at least a part of an area of said device said pixel interface circuitry is staggered with respect to said pixels such that a region under a pair of adjacent pixels is incompletely occupied by said pixel interface circuitry.

3. An organic electro-optic device as claimed in claim 1 wherein said additional circuitry includes at least one semiconductor device.

4. An organic electro-optic device as claimed in claim 1 wherein said regions are provided at regular intervals across an area of said display.

5. An organic electro-optic device as claimed in claim 1 wherein said additional circuitry comprises shared interface circuitry to provide an interface to a group of said pixels.

6. An organic electro-optic device as claimed in claim 5 wherein said shared interface circuitry comprises a signal regeneration circuit.

7. An organic electro-optic device as claimed in claim 5 wherein said shared interface circuitry includes a de-amplifying current mirror.

8. An organic electro-optic device as claimed in claim 1 wherein said additional circuitry includes a select or enable circuit to select or enable drive circuitry for a group of pixels with which said additional circuitry is associated.

9. An organic electro-optic device as claimed in claim 1 wherein said additional circuitry includes a memory element.

10. An organic electro-optic device as claimed in claim 1 wherein said additional circuitry comprises a light sensor or touch sensor.

11. An organic electro-optic device as claimed in claim 10 wherein said device comprises a touch-sensitive display.

12. An organic electro-optic device as claimed in claim 1 wherein said device comprises a top-emitting active matrix OLED structure, wherein said pixel interface circuitry comprises pixel drive circuitry, and wherein said organic material comprises OLED material over said pixel drive circuitry, whereby said structure is configured to emit light from a top surface.

13. A method of driving a pixelated display, the display having a plurality of active matrix pixels each with a data line for writing display data to the pixel, a said data line being shared for driving a plurality of pixels of said display, pixels driven by a said shared data line being allocated to groups, each group comprising multiple pixels and having a respective group data driver circuit coupled to said shared data line and to each pixel of the group for receiving pixel drive data from said shared data line and for driving a selected pixel of the group responsive to said pixel drive data, the method comprising:
driving a first pixel of each of said groups in turn; and
then driving a second pixel of each of said groups in turn.

14. A method as claimed in claim 13 further comprising repeating said driving for a third and each subsequent pixel of each of said groups in turn to drive substantially all said pixels driven by said shared data line.

15. A method as claimed in claim 13 wherein a said shared data line comprises a row or column data line of said display.

16. A method as claimed in claim 13, wherein said driving comprises storing a drive signal for a driven pixel of a said group using the respective group data driver circuit for the group.

17. A method as claimed in claim 13 wherein said driving of a pixel comprises buffering a drive signal on said shared data line using said group data driver circuit, and driving said pixel with said buffered drive signal.

18. A method as claimed in claim 17 wherein said drive signal comprises a current drive signal, wherein each said pixel has associated current drive circuitry, and wherein said buffering comprises reducing a level of said current drive signal to provide a reduced current drive signal to said pixel current drive circuitry.

19. A method as claimed in claim 18 wherein said buffering comprises using a current mirror circuit to de-amplify said level of said current drive signal.

20. A method as claimed in claim 13 further comprising locating a said group data driver circuit adjacent a pixel in a group driven by said group data driver circuit.

21. A method as claimed in claim 13 wherein a said active matrix pixel has active matrix drive circuitry, and wherein said active matrix drive circuitry for pixels of a said group is displaced to allow a said group data driver circuit to be included in said display alongside said active matrix circuitry for pixels of the group.

22. A method as claimed in claim 13 wherein said display comprise a flat panel display.

23. A method as claimed in claim 13 wherein said display comprises a top-emitting active matrix OLED display.

24. A pixelated display, the display having a plurality of active matrix pixels each with a data line for writing display data to the pixel, a said data line being shared for driving a plurality of pixels of said display, pixels driven by a said shared data line being allocated to groups, each group comprising multiple pixels and having a respective group data driver circuit coupled to said shared data line and to each pixel of the group for receiving pixel drive data from said shared data line and for driving a selected pixel of the group responsive to said pixel drive data.

25. A display as claimed in claim 24 wherein said display comprises a flat panel display.

26. A display as claimed in claim 24 wherein said display comprises a top-emitting active matrix electroluminescent display.

27. A display as claimed in claim 24 wherein a said active matrix pixel has active matrix drive circuitry, and wherein said active matrix drive circuitry for pixels of a said group is displaced to allow a said group data driver circuit to be included in said display alongside said active matrix circuitry for pixels of the group.
